(19) United States
(12) Patent Application Publication
(10) Pub. No.: US 2026/0239752 A1
(43) Pub. Date: Aug. 13, 2026

(54) PHOTOELECTRIC CONVERSION APPARATUS AND PHOTOELECTRIC CONVERSION SYSTEM

(71) Applicant: CANON KABUSHIKI KAISHA, Tokyo (JP)

(72) Inventor: DAIKI SHIRAHIGE, Kanagawa (JP)

(21) Appl. No.: 19/530,541

(22) Filed: Feb. 5, 2026

(30) Foreign Application Priority Data
Feb. 10, 2025 (JP) 2025-020247

(51) Int. Cl. H10F 39/00

(52) U.S. Cl. CPC H10F 39/8023; H10F 39/807; H10F 39/811

(57) ABSTRACT

A photoelectric conversion apparatus includes a semiconductor layer having first and second surfaces, first electrodes contacting the first surface, and a second electrode contacting the second surface. The semiconductor layer includes a pixel isolation portion constituted by an insulator arranged between adjacent pixels. Each pixel includes a first semiconductor region of first conductivity type arranged in the semiconductor layer and electrically connected to one of the first electrodes, and a second semiconductor region of second conductivity type arranged in the semiconductor layer and electrically connected to the second electrode. The semiconductor layer includes a third semiconductor region of the second conductivity type contacting the second electrode and electrically connected to the second semiconductor region. A contact region between the second electrode and the second surface overlaps the insulator in orthogonal projection to the first surface.

### BACKGROUND

### Field of the Technology

The present disclosure relates to a photoelectric conversion apparatus and a photoelectric conversion system.

### Description of the Related Art

Japanese Patent Laid-Open No. 2022-023393 describes SPAD pixels in which a plurality of pixels isolated by a trench isolation portion. In the SPAD pixel described in Japanese Patent Laid-Open No. 2022-023393, a semiconductor region of the second conductivity type is arranged in the light incident surface of a region surrounded by the trench isolation portion, and the semiconductor region of the second conductivity type is supplied with a potential via a contact plug. Since the contact plug is arranged inside the pixel relative to the trench isolation portion in a planar view, light entering the pixel may be obstructed. This can lower the sensitivity of the SPAD pixel. This problem can become more pronounced as the pixels are miniaturized.

### SUMMARY

The present disclosure provides a technique advantageous in improving the sensitivity of a photoelectric conversion apparatus.

The present disclosure provides a photoelectric conversion apparatus including a plurality of pixels, comprising a semiconductor layer including a first surface and a second surface, a plurality of first electrodes arranged in contact with the first surface, and at least one second electrode arranged in contact with the second surface, wherein the semiconductor layer includes a pixel isolation portion constituted by an insulator arranged between adjacent pixels of the plurality of pixels, each pixel includes a first semiconductor region of a first conductivity type arranged in the semiconductor layer and electrically connected to one of the plurality of first electrodes, and a second semiconductor region of a second conductivity type arranged in the semiconductor layer and electrically connected to the second electrode, the semiconductor layer includes a third semiconductor region of the second conductivity type being in contact with the second electrode and electrically connected to the second semiconductor region, and a contact region between the second electrode and the second surface overlaps the insulator in an orthogonal projection to the first surface.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view showing an example of the arrangement of a photoelectric conversion apparatus according to an embodiment;

FIG. 2 is a view showing an example of the arrangement of the first substrate;

FIG. 3 is a view showing an example of the arrangement of the second substrate;

FIG. 4 is a view showing an example of the arrangement of a photoelectric conversion element and a pixel circuit;

FIGS. 5A to 5C are views for explaining a photon detection operation;

FIG. 6 is a view showing an example of the arrangement of a photoelectric conversion apparatus according to the first embodiment;

FIG. 7 is a view showing an example of the arrangement of the photoelectric conversion apparatus according to the first embodiment;

FIG. 8 is a view showing an example of the arrangement of the photoelectric conversion apparatus according to the first embodiment;

FIG. 9 is a view showing an example of the arrangement of the photoelectric conversion apparatus according to the first embodiment;

FIG. 10 is a view showing an example of the arrangement of a photoelectric conversion apparatus according to the second embodiment;

FIG. 11 is a view showing an example of the arrangement of the photoelectric conversion apparatus according to the second embodiment;

FIG. 12 is a view showing an example of the arrangement of the photoelectric conversion apparatus according to the second embodiment;

FIG. 13 is a view showing an example of the arrangement of a photoelectric conversion apparatus according to the third embodiment;

FIG. 14 is a view showing an example of the arrangement of a photoelectric conversion apparatus according to the fourth embodiment;

FIGS. 15A and 15B are views each showing an example of the arrangement of the photoelectric conversion apparatus according to the fourth embodiment;

FIG. 16 is a view showing an example of the arrangement of a photoelectric conversion apparatus according to the fifth embodiment;

FIG. 17 is a view showing an example of the arrangement of a photoelectric conversion apparatus according to the sixth embodiment;

FIG. 18 is a functional block diagram of a photoelectric conversion system according to the first application example;

FIGS. 19A and 19B are functional block diagrams of a photoelectric conversion system according to the second application example;

FIG. 20 is a functional block diagram of a photoelectric conversion system according to the third application example;

FIG. 21 is a functional block diagram of a photoelectric conversion system according to the fourth application example;

FIGS. 22A and 22B are functional block diagrams of a photoelectric conversion system according to the fifth application example;

FIGS. 23A and 23B are functional block diagrams of a photoelectric conversion system according to the sixth application example; and

FIG. 24 is a functional block diagram of a photoelectric conversion system according to the seventh application example.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In this specification, mutually different conductivity types of semiconductor regions are distinguished as the first conductivity type and the second conductivity type. The first conductivity type is a conductivity type which uses charge with the first polarity as a majority carrier, and the second conductivity type is a conductivity type which uses charge with the second polarity as a majority carrier. In a case where the first polarity is positive, the charge with the first polarity is a hole, the first conductivity type is the p type, the second polarity is negative, the charge with the second polarity is an electron, and the second conductivity type is the n type. To the contrary, in a case where the first polarity is negative, the charge with the first polarity is an electron, the first conductivity type is the n type, the second polarity is positive, the charge with the second polarity is a hole, and the second conductivity type is the p type.

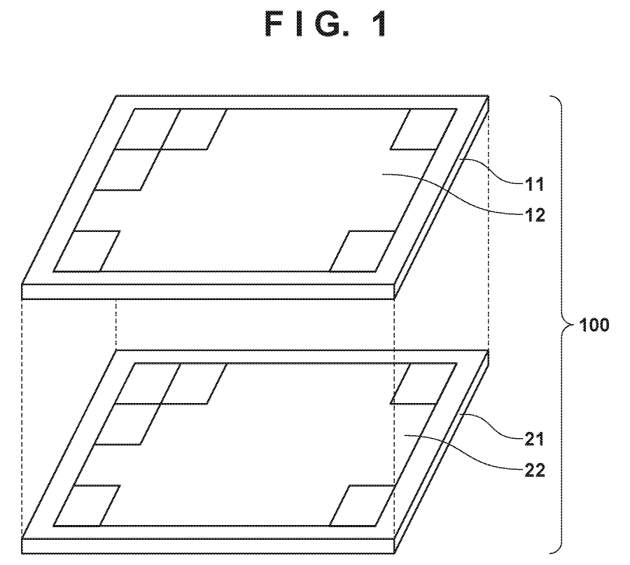

FIG. 1 schematically shows an example of the arrangement of a photoelectric conversion apparatus 100 according to an embodiment of the present disclosure. The photoelectric conversion apparatus 100 can have, for example, a structure in which a first substrate 11 and a second substrate 21 are stacked. The first substrate 11 can include, for example, a photoelectric conversion element array 12 including a plurality of photoelectric conversion elements (APDs). The second substrate 21 can include a processing circuit 22 that processes signals output from the plurality of photoelectric conversion elements.

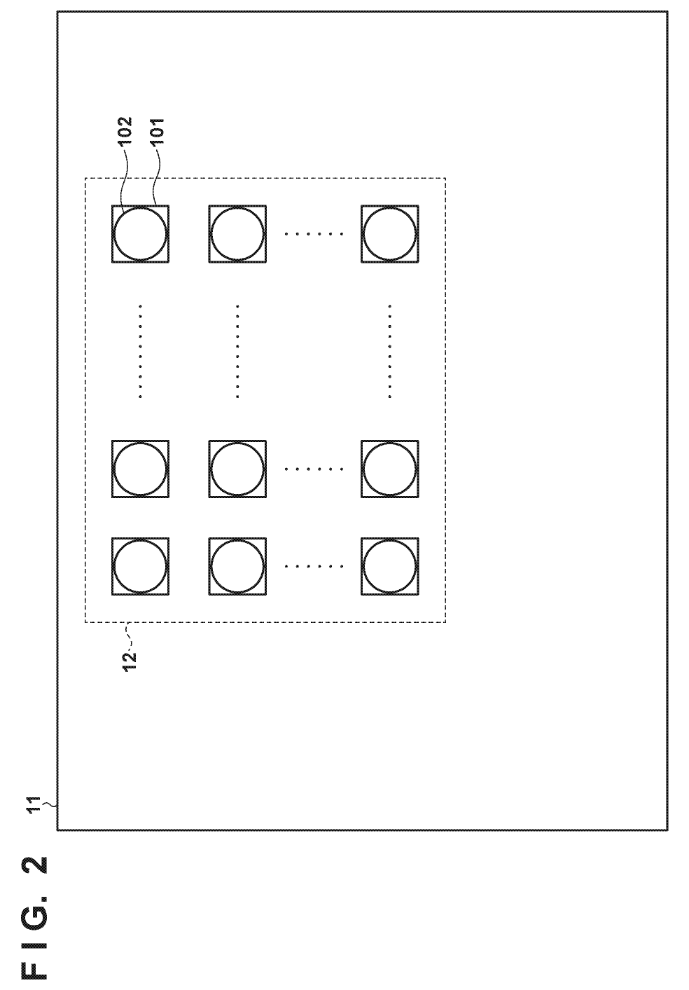

FIG. 2 schematically shows an example of the arrangement of the first substrate 11. The photoelectric conversion element array 12 of the first substrate 11 can include a plurality of photoelectric conversion elements 102 arranged to form a plurality of rows and a plurality of columns. Each photoelectric conversion element 102 constitutes a part of a pixel 101. The photoelectric conversion apparatus 100 will exemplarily be described below as an image capturing apparatus. However, the photoelectric conversion apparatus 100 may be formed as another apparatus. For example, the photoelectric conversion apparatus 100 can be formed as a distance measurement apparatus (for example, a focus detection apparatus or a distance measurement apparatus using TOF (Time Of Flight)) or a photometric apparatus (an apparatus for, for example, measuring an incident light amount). Note that a plurality of pixels 101 may linearly be arranged. In this case, the photoelectric conversion apparatus 100 can form a line sensor.

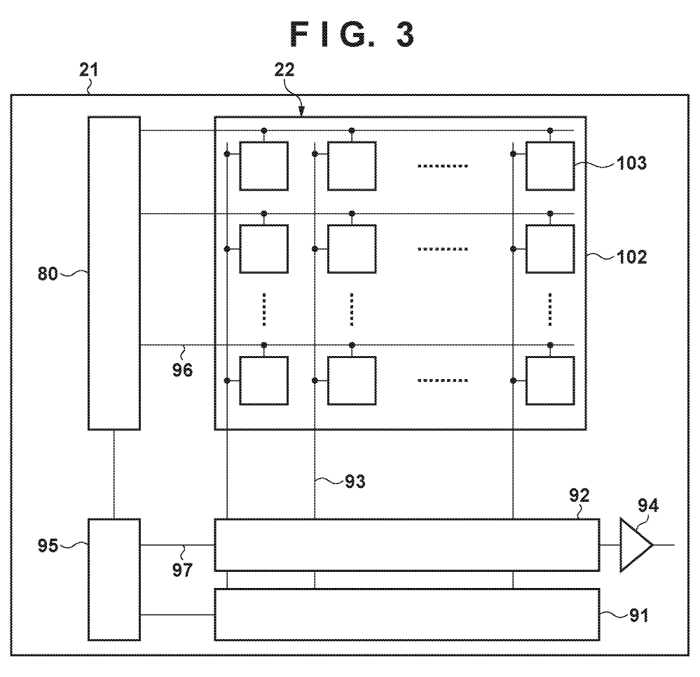

FIG. 3 schematically shows the arrangement of the processing circuit 22 of the second substrate 21. The processing circuit 22 can include, for example, a pixel circuit array 120 including a plurality of pixel circuits 103, a readout circuit 92, a control unit 95, a horizontal scanning circuit 91, a plurality of signal lines 93, a vertical scanning circuit 80, and an output unit 94. Each pixel circuit 103 constitutes the pixel 101 together with the corresponding photoelectric conversion element 102, and processes a signal output from the photoelectric conversion element 102. One pixel circuit 103 may be provided for one photoelectric conversion element 102, or one pixel circuit 103 may be provided for two or more photoelectric conversion elements 102. In an example, one photoelectric conversion element 102 and one pixel circuit 103 can be electrically connected by a connection portion. The pixel circuit 103 can include, for example, a counter and a memory. The memory can hold a count value obtained by counting by the counter. The photoelectric conversion element array 12 and the pixel circuit array 120 constitute a pixel array.

For example, the vertical scanning circuit 80 can sequentially select a plurality of rows of the photoelectric conversion element array 12 in accordance with a control signal supplied from the control unit 95. The vertical scanning circuit 80 can include, for example, at least one of a shift register and an address decoder. The readout circuit 92 reads out signals output, via the plurality of signal lines 93, from the pixel circuits 103 corresponding to the pixels 101 of the row selected by the vertical scanning circuit 80. For example, the horizontal scanning circuit 91 supplies to the output unit 94, in a predetermined order, the signals for one row read out by the readout circuit 92.

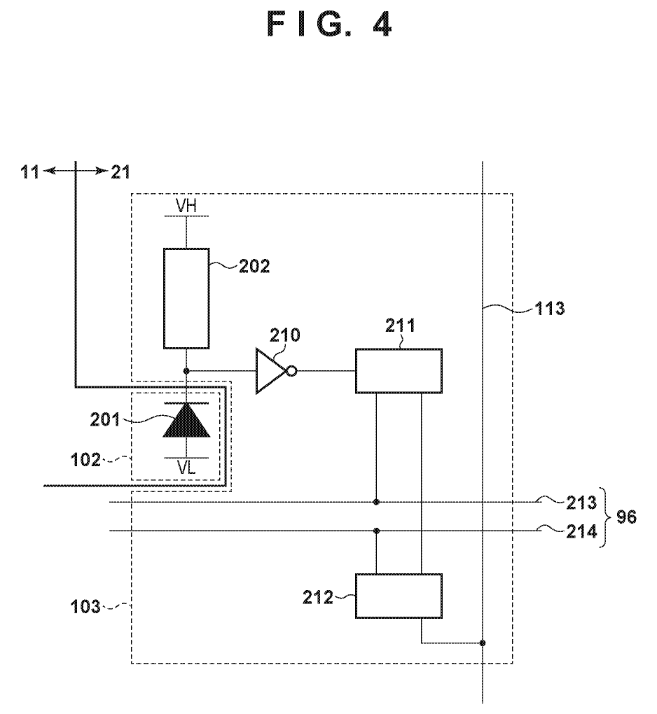

FIG. 4 shows an example of the arrangement of the photoelectric conversion element 102 and the pixel circuit 103. In the example shown in FIG. 4, one pixel circuit 103 is assigned to one photoelectric conversion element 102. The photoelectric conversion element 102 includes an APD 201. At least one of a plurality of components of the pixel circuit 103 may be arranged on the first substrate 11. Alternatively, all the plurality of components of the pixel circuit 103 may be arranged on the first substrate 11.

A first voltage VH can be applied to the cathode of the APD 201. A second voltage VL is applied to the anode of the APD 201, and the first voltage VH has a potential higher than the potential of the second voltage VL. A potential difference between the first voltage VH and the second voltage VL is applied to the APD 201 (between the anode and cathode of the APD 201). This potential difference is a reverse bias voltage that causes the APD 201 to perform an avalanche multiplication operation. Charges generated by photons entering the APD 201 cause avalanche multiplication, thereby generating an avalanche current. A mode of applying a voltage higher than the breakdown voltage of the APD 201 between the anode and cathode of the APD 201 is called a Geiger mode. A mode of applying a voltage around or lower than the breakdown voltage between the anode and cathode of the APD 201 is called a linear mode. An APD operating in the Geiger mode is called an SPAD. In an example, the first voltage VH is 1 V, and the second voltage VL is -30 V.

The pixel circuit 103 can include a quenching element 202 connected between the cathode of the APD 201 and a terminal supplied with the first voltage VH. The quenching element 202 may be understood as an element that supplies the first voltage VH to the cathode of the APD 201. The quenching element 202 has a function of converting the change of the avalanche current generated in the APD 201 into a voltage signal. The quenching element 202 functions as a load circuit (quenching circuit) at the time of signal multiplication by avalanche multiplication, and serves to suppress avalanche multiplication by suppressing the voltage applied to the APD 201. This is known as a quenching operation.

The pixel circuit 103 can additionally include, for example, at least one of a waveform shaping unit 210, a counter circuit 211, and a selection circuit 212. The waveform shaping unit 210 can output a pulse signal by shaping the potential change of the cathode of the APD 201 at the time of detection of a photon. The waveform shaping unit 210 can include, for example, an inverter circuit. In the example shown in FIG. 4, the waveform shaping unit 210 is formed by one inverter, but the waveform shaping unit 210 may be formed by series-connecting a plurality of inverters or by another circuit having the waveform shaping effect.

The counter circuit 211 can be configured to count a pulse signal output from the waveform shaping unit 210 and hold a count value obtained by counting. When a first control pulse of an active level is supplied from the vertical scanning circuit 80 via a driving line 213, the signal held in the counter circuit 211 can be reset. When a second control pulse of an active level is supplied from the vertical scanning circuit 80 via a driving line 214, the selection circuit 212 can electrically connect the counter circuit 211 and the signal line 93. The selection circuit 212 can include, for example, a buffer circuit.

In this example, the counter circuit 211 is provided. However, the photoelectric conversion apparatus 100 may be configured to acquire a pulse detection timing by providing a Time-to-Digital Converter (to be referred to as a TDC hereinafter), instead of the counter circuit 211. In this case, the generation timing of the pulse signal output from the waveform shaping unit 210 can be converted into a digital signal by the TDC. A reference pulse (reference signal) can be supplied from the vertical scanning circuit 80 to the TDC via a driving line to measure the timing of the pulse signal. With reference to the reference pulse, the TDC can generate a digital signal corresponding to the generation timing of the pulse signal output from the waveform shaping unit 210.

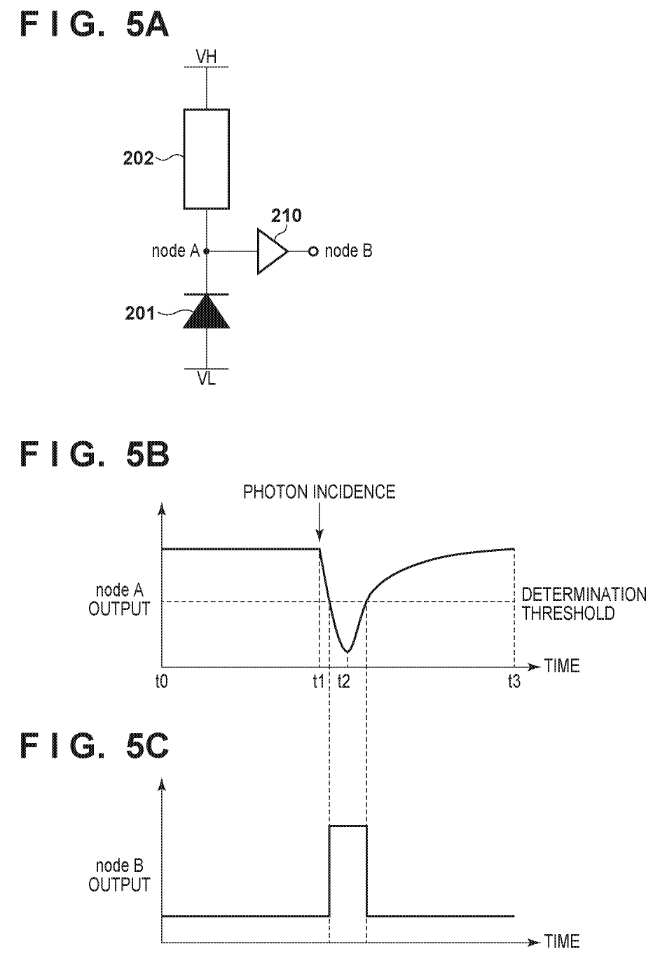

FIGS. 5A to 5C are views for explaining a photon detection operation by the photoelectric conversion apparatus 100. FIG. 5A is a view showing an excerpt of the APD 201, the quenching element 202, and the waveform shaping unit 210 from FIG. 4. The input side of the waveform shaping unit 210 is a node A and the output side of the waveform shaping unit 210 is a node B. FIG. 5B shows the waveform at the node A of FIG. 5A and FIG. 5C shows the waveform at the node B of FIG. 5A. From time t0 to time t1, a potential difference of VH - VL is applied to the APD 201. When a photon enters at time t1, avalanche multiplication occurs in the APD 201. This causes an avalanche multiplication current to flow into the quenching element 202, and the voltage (potential) of the node A drops. When the voltage drop amount increases and the potential difference applied to the APD 201 decreases, the avalanche multiplication of the APD 201 stops. After that, a current compensating for the voltage drop from the voltage VL flows into the node A, and the node A is statically determined at the original potential level at time t3. At this time, a portion at which the output waveform exceeds a given threshold at the node A is waveform-shaped by the waveform shaping unit 210 and a pulse signal appears at the node B.

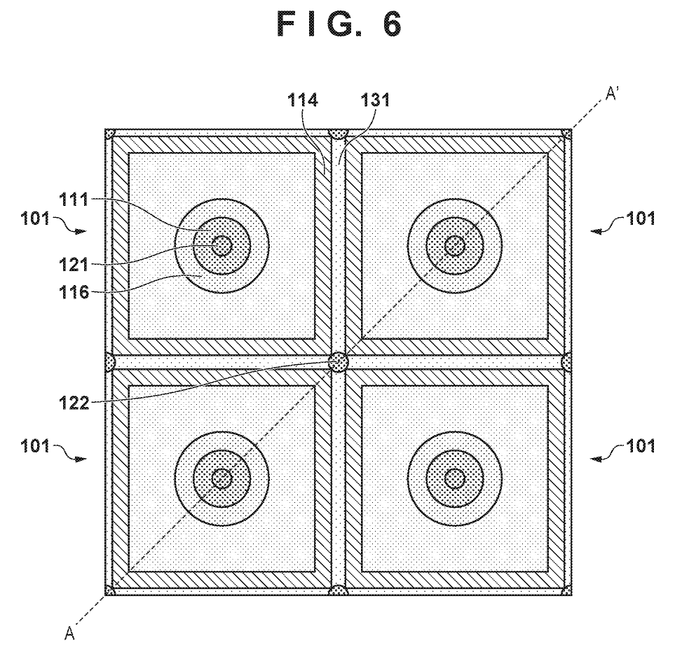

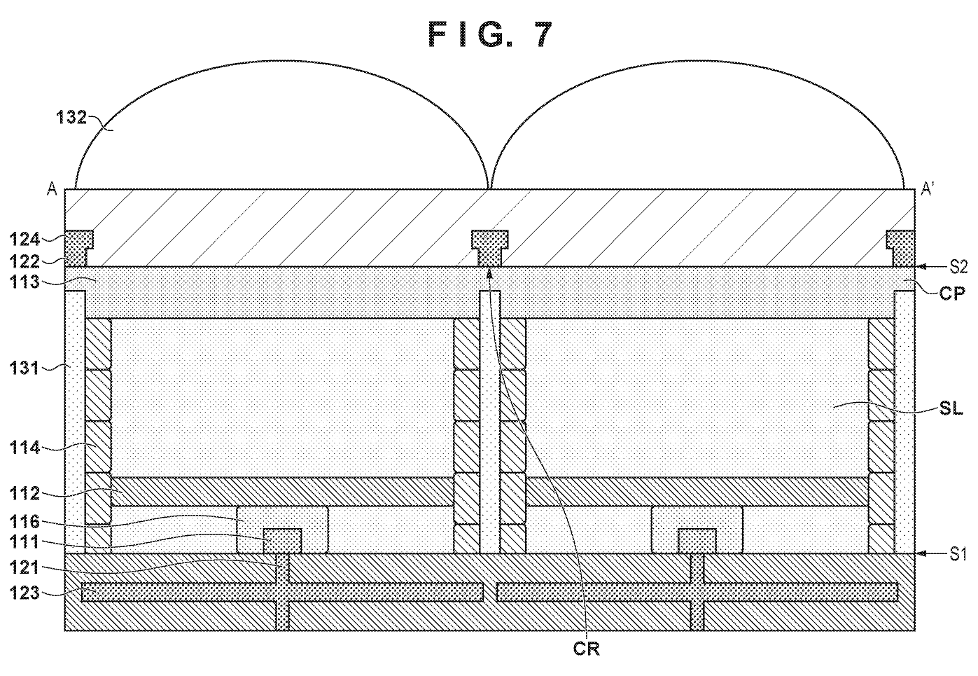

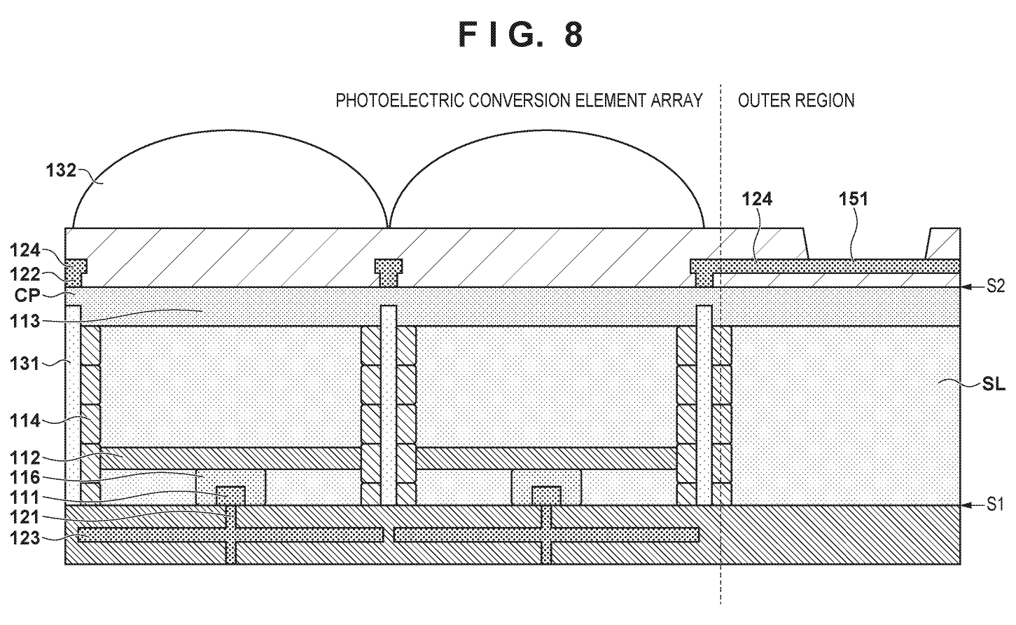

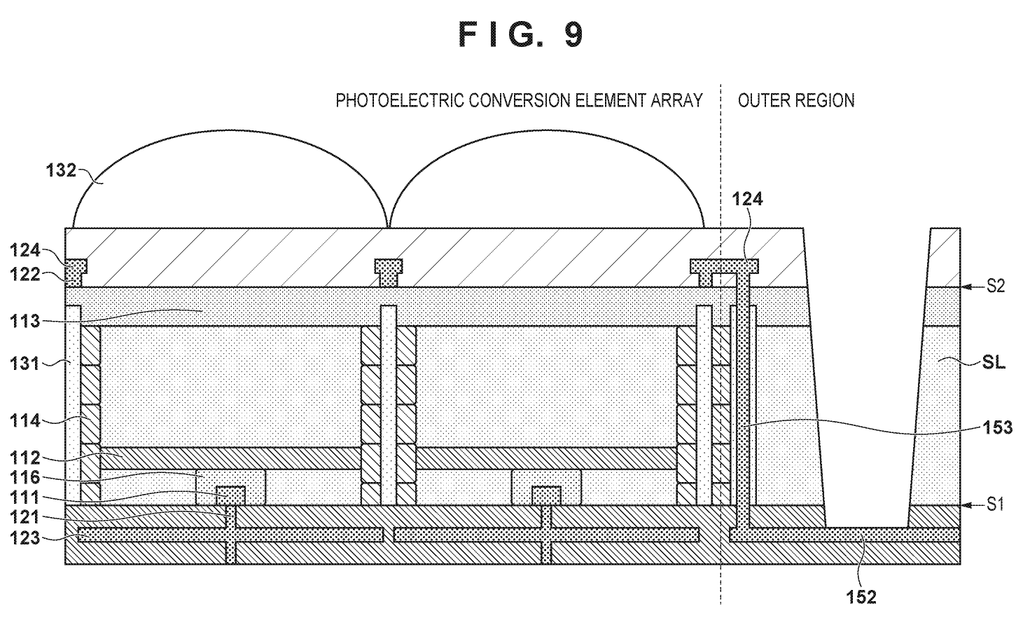

With reference to FIGS. 6 to 9, a photoelectric conversion apparatus 100 according to the first embodiment will be described below. FIG. 6 is a plan view schematically showing the arrangement of four pixels 101 of a plurality of pixels 101 of the photoelectric conversion apparatus 100. In the plan view, various components arranged at different depths are shown in a superimposed manner. FIG. 7 is a schematic sectional view taken along a line A - A' in FIG. 6. FIG. 8 is a sectional view schematically showing an example of the arrangement near the boundary between a photoelectric conversion element array 12 and the outer region thereof. FIG. 9 is a sectional view schematically showing another example of the arrangement near the boundary between the photoelectric conversion element array 12 and the outer region thereof.

The photoelectric conversion apparatus 100 or a first substrate 11 can include a semiconductor layer SL including a first surface S1 and a second surface S2, a plurality of first electrodes 121 arranged in contact with the first surface S1, and at least one second electrode 122 arranged in contact with the second surface S2. The number of the first electrodes 121 included in the photoelectric conversion apparatus 100 may be the same as the number of the plurality of pixels 101 included in the photoelectric conversion apparatus 100. The number of the second electrodes 122 included in the photoelectric conversion apparatus 100 may be the same as the number of the plurality of pixels 101 included in the photoelectric conversion apparatus 100, may be larger than the number of the plurality of pixels 101, or may be smaller than the number of the plurality of pixels 101.

The semiconductor layer SL includes a pixel isolation portion 131 arranged between adjacent pixels 101 of the plurality of pixels 101. The pixel isolation portion 131 is constituted by an insulator. The insulator constituting the pixel isolation portion 131 can be formed of, for example, silicon oxide, silicon nitride, or silicon oxynitride. The insulator may include a fixed charge film made of aluminum oxide, tantalum oxide, or the like that induces the charge with the second polarity. Each pixel 101 is surrounded by the pixel isolation portion 131. The first electrode 121 can be supplied with a first voltage VH through a first wiring pattern 123. The second electrode 122 can be supplied with a second voltage VL through a second wiring pattern 124.

Each pixel 101 can include a first semiconductor region 111 of the first conductivity type which is arranged in the semiconductor layer SL and is electrically connected to one of the plurality of first electrodes 121, and a second semiconductor region 112 of the second conductivity type electrically connected to the second electrode 122 arranged in the semiconductor layer SL. A contact region CR between the second electrode 122 and the second surface S2 can be arranged to overlap the pixel isolation portion 131 (that is, the insulator) in an orthogonal projection (planar view) to the first surface S1. This arrangement is advantageous for reducing the area where light entering the second surface S2 is blocked by the second electrode 122, thereby improving the sensitivity of the photoelectric conversion apparatus 100.

In the example shown in FIG. 6, the plurality of pixels 101 are arranged to form a rectangular lattice, and the contact region CR between the second electrode 122 and the second surface S2 is arranged to overlap a lattice point of the rectangular lattice. This arrangement is advantageous in improving the sensitivity of the photoelectric conversion apparatus 100, but the contact region CR may be arranged at another position, for example, between adjacent lattice points.

In FIG. 7, the width (the width in a direction parallel to the first surface S1: the same applied hereafter) of the pixel isolation portion 131 is constant regardless of the distance from the first surface S1. However, a shape in which the width of a portion of the pixel isolation portion 131 closest to the second surface S2 is smaller than the width of the pixel isolation portion 131 at the first surface S1 may be adopted instead. This structure is advantageous in improving the sensitivity of the photoelectric conversion apparatus 100. In this arrangement, the width of the contact region CR is preferably smaller than the width of the portion of the pixel isolation portion 131 closest to the second surface S2, and further preferably smaller than the width of the pixel isolation portion 131 at the first surface S1. The photoelectric conversion apparatus 100 includes the second wiring pattern 124 connected to the second electrode 122. The width of the second wiring pattern 124, which is arranged in a region overlapping the pixel isolation portion 131 (that is, insulator) in the planar view, is preferably smaller than the width of the pixel isolation portion 131.

The semiconductor layer SL can further include a third semiconductor region 113 of the second conductivity type. The third semiconductor region 113 is in contact with any of at least one second electrode 122, and electrically connected to the second semiconductor region 112. The third semiconductor region 113 can be arranged to extend across the plurality of pixels 101. The third semiconductor region 113 can include a portion CP arranged between the second surface S2 and the pixel isolation portion 131. The pixel isolation portion 131 can include a portion extending from the first surface S1 to a position in the third semiconductor region 113.

The semiconductor layer SL can include a fourth semiconductor region 114 of the second conductivity type arranged in contact with the side surface of the pixel isolation portion 131. The fourth semiconductor region can be arranged to electrically connect the second semiconductor region 112 and the third semiconductor region 113. The semiconductor layer SL can further include a fifth semiconductor region 116 of the first conductivity type arranged between the first semiconductor region 111 and the second semiconductor region 112 so as to surround the side surface of the first semiconductor region 111. The impurity concentration of the first conductivity type in the fifth semiconductor region 116 may be lower than the impurity concentration of the first conductivity type in the first semiconductor region 111 so that the field intensity between the first semiconductor region 111 and the second semiconductor region 112 is relaxed.

The photoelectric conversion apparatus 100 may include a plurality of microlenses 132. Light having entered the photoelectric conversion apparatus 100 and passed through the microlens 132 can enter the second surface S2 and undergo photoelectric conversion in the semiconductor layer SL, thereby generating charges. Between the first semiconductor region 111 and the second semiconductor region 112, a strong electric field is generated, and an avalanche multiplication region is formed. The charges generated by photoelectric conversion are absorbed by the avalanche multiplication region, and this can cause avalanche multiplication.

As illustrated in FIG. 8, the second wiring pattern 124 can be supplied with the second voltage VL from a pad 151 arranged on the second surface S2 side. Alternatively, as illustrated in FIG. 9, the second wiring pattern 124 can be supplied with the second voltage VL from a pad 152 arranged on the first surface S1 side via a via 153.

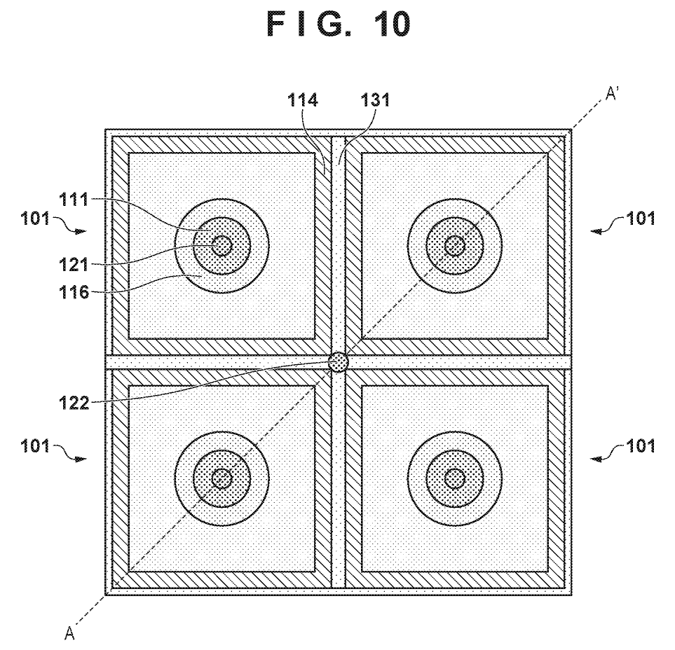

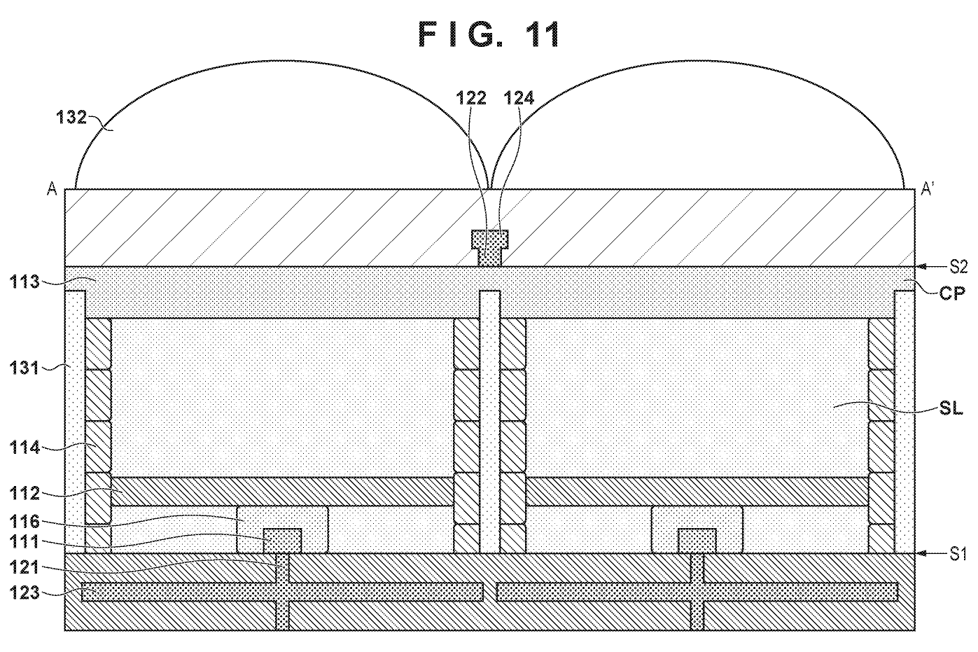

With reference to FIGS. 10 and 11, a photoelectric conversion apparatus 100 according to the second embodiment will be described below. Matters not mentioned in the second embodiment can follow the first embodiment. FIG. 10 is a plan view schematically showing the arrangement of four pixels 101 of a plurality of pixels 101 of the photoelectric conversion apparatus 100. In the plan view, various components arranged at different depths are shown in a superimposed manner. FIG. 11 is a schematic sectional view taken along a line A - A' in FIG. 10.

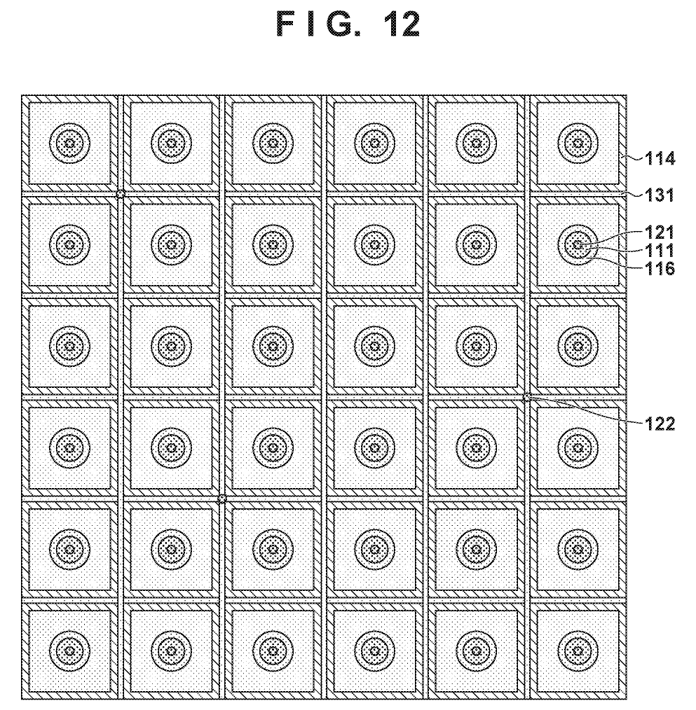

In the second embodiment, the number (total number) of second electrodes 122 included in the photoelectric conversion apparatus 100 is smaller than the number (total number) of a plurality of pixels 101 included in the photoelectric conversion apparatus 100. In the example shown in FIG. 10, one second electrode 122 is arranged at the center of the aggregate of four pixels 101 arranged to form two rows and two columns. From another viewpoint, in the example shown in FIG. 10, one second electrode 122 is arranged for the aggregate of four pixels 101. Decreasing the number of second electrodes 122 suppresses unintended impurities and defects that can be introduced in a semiconductor layer SL to form the second electrode 122. This is expected to contribute to reduction of DCRs and hot pixels. FIG. 12 shows another example of the photoelectric conversion apparatus 100 according to the second embodiment. In the example shown in FIG. 12, the number of the second electrodes 122 is smaller than in the example shown in FIG. 10.

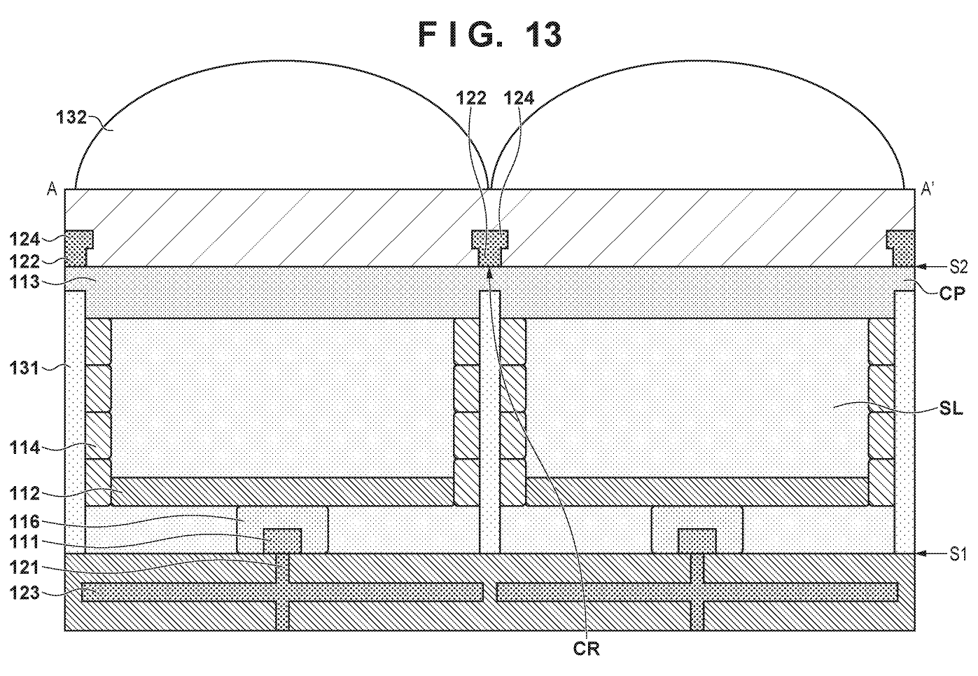

With reference to FIG. 13, a photoelectric conversion apparatus 100 according to the third embodiment will be described below. Matters not mentioned in the third embodiment can follow the first or second embodiment. FIG. 6 is cited as a view showing the arrangement of the photoelectric conversion apparatus 100 according to the third embodiment. FIG. 13 is a schematic sectional view taken along a line A - A' in FIG. 6.

In the third embodiment, a fourth semiconductor region 114 is arranged spaced apart from a first surface S1. From another viewpoint, the fourth semiconductor region 114 is arranged not to surround a first semiconductor region 111. Alternatively, the fourth semiconductor region 114 is arranged not to surround a fifth semiconductor region 116. In the third embodiment, as compared to the first embodiment, the distance between the fourth semiconductor region 114 and the first semiconductor region 111 is large. From another viewpoint, in the third embodiment, as compared to the first embodiment, the distance between the fourth semiconductor region 114 and the fifth semiconductor region 116 is large. This can relax the field intensity between the fourth semiconductor region 114 and the first semiconductor region 111, or the field intensity between the fourth semiconductor region 114 and the fifth semiconductor region 116. Therefore, a dark current can be reduced.

In a case where a pixel isolation portion 131 includes a fixed charge film made of aluminum oxide, tantalum oxide, or the like that induces the charge with the second polarity, the fixed charge film can also be arranged spaced apart from the first surface S1.

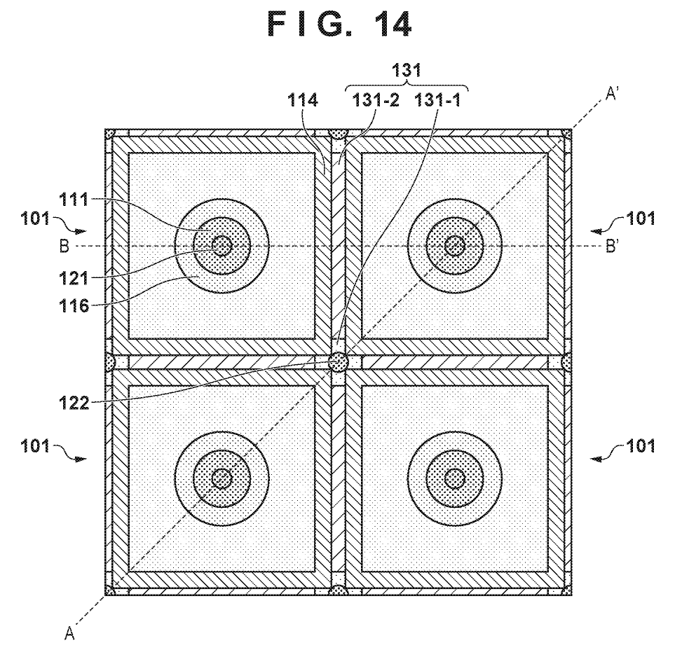

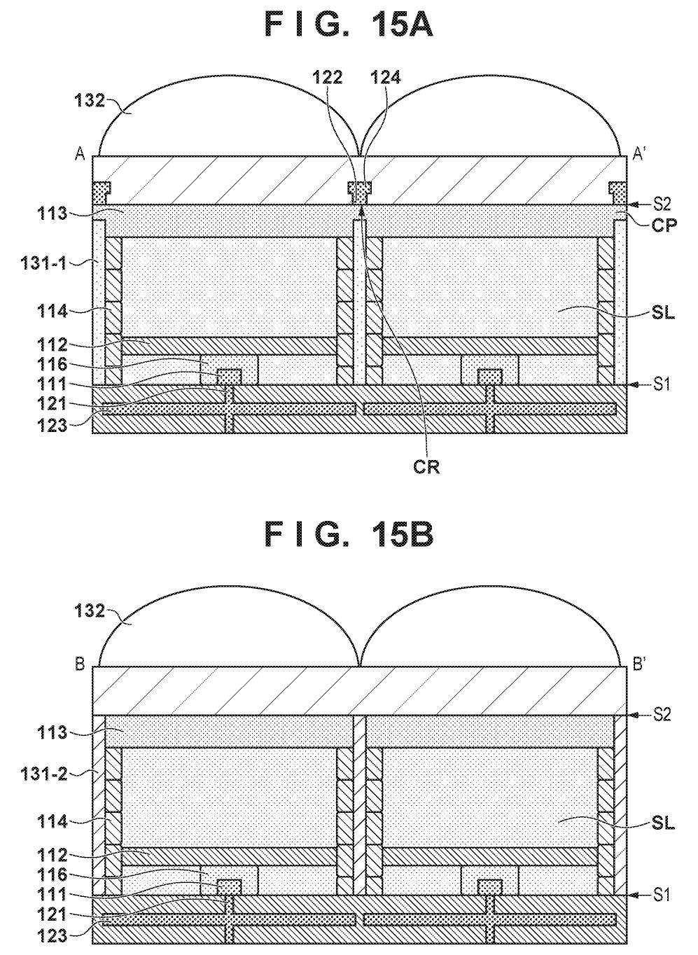

With reference to FIGS. 14 to 15B, a photoelectric conversion apparatus 100 according to the fourth embodiment will be described below. Matters not mentioned in the fourth embodiment can follow the first to third embodiments. FIG. 14 is a plan view schematically showing the arrangement of four pixels 101 of the plurality of pixels 101 of the photoelectric conversion apparatus 100. In the plan view, various components arranged at different depths are shown in a superimposed manner. FIG. 15A is a schematic sectional view taken along a line A - A' in FIG. 14. FIG. 15B is a schematic sectional view taken along a line B - B' in FIG. 14.

In the fourth embodiment, a pixel isolation portion 131 includes a first portion 131-1 spaced apart from a second surface S2, and a second portion 131-2 in contact with the second surface S2. A third semiconductor region 113 can include a portion CP arranged between the second surface S2 and the first portion 131-1. The pixel isolation portion 131 can be formed by, for example, forming a trench by etching a semiconductor layer SL from the side of a first surface S1 to a predetermined depth, and etching, from the second surface S2 side to the trench, only the region of the semiconductor layer SL where the first portion 131-1 is to be arranged.

In the example shown in FIG. 14, the plurality of pixels 101 are arranged to form a rectangular lattice, and a contact region CR and the first portion 131-1 are arranged to overlap a lattice point of the rectangular lattice. This arrangement is advantageous in improving the sensitivity of the photoelectric conversion apparatus 100. The second portion 131-2 can be arranged between adjacent lattice points of the rectangular lattice. This arrangement is advantageous for reducing crosstalk between the adjacent pixels 101.

In place of the arrangement described above, the pixel isolation portion 131 may be formed such that the distance between the second surface S2 and the first portion 131-1 is smaller than the distance between the second surface S2 and the second portion 131-2.

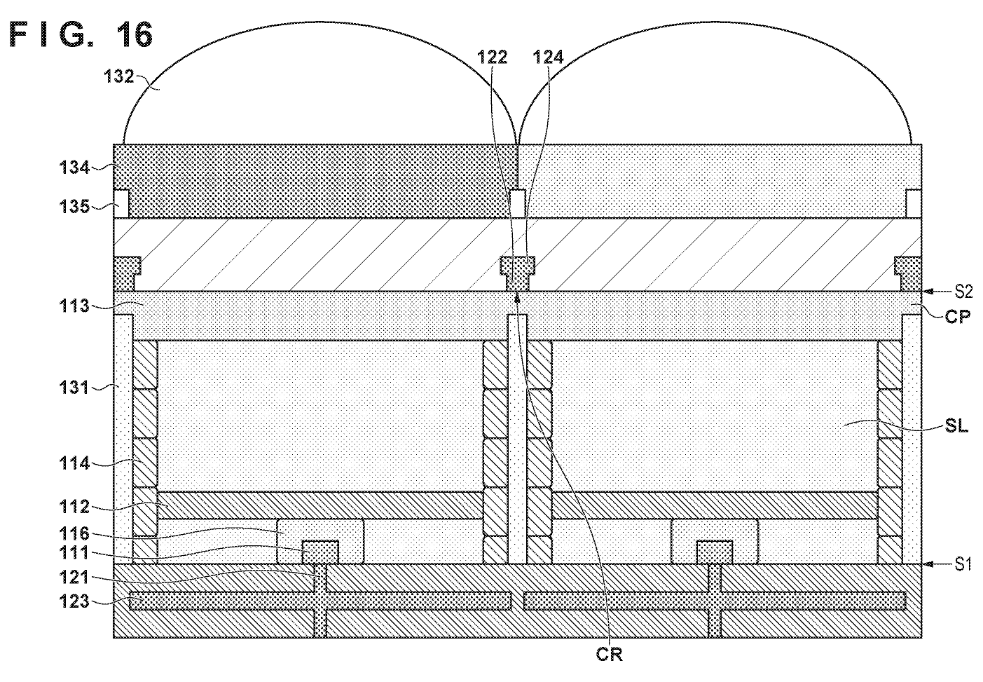

With reference to FIG. 16, a photoelectric conversion apparatus 100 according to the fifth embodiment will be described below. Matters not mentioned as the fifth embodiment can follow the first to fourth embodiments. FIG. 6 is cited as a view showing the arrangement of the photoelectric conversion apparatus 100 according to the fifth embodiment. FIG. 16 is a schematic sectional view taken along a line A - A' in FIG. 6. In the fifth embodiment, the photoelectric conversion apparatus 100 includes a plurality of color filters 134. A grid 135 can be arranged on the boundary between the adjacent color filters 134. The grid 135 may be formed of a metal, or may be formed of a material having a lower refractive index than the color filter 134. At least one of a second electrode 122 and the grid 135 can be adjusted in position in accordance with the position (image height) of a pixel 101.

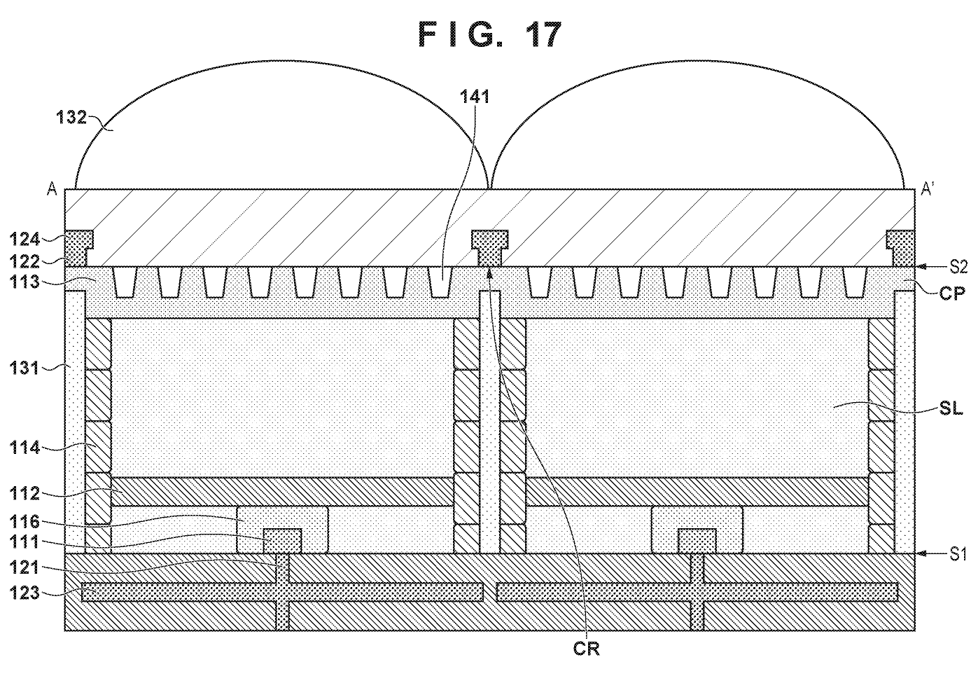

With reference to FIG. 17, a photoelectric conversion apparatus 100 according to the sixth embodiment will be described below. Matters not mentioned as the sixth embodiment can follow the first to fifth embodiments. FIG. 6 is cited as a view showing the arrangement of the photoelectric conversion apparatus 100 according to the sixth embodiment. FIG. 17 is a schematic sectional view taken along a line A - A' in FIG. 6. In the sixth embodiment, the photoelectric conversion apparatus 100 includes an optical structure 141 that scatters and/or diffracts light. The optical structure 141 can be formed by, for example, forming a recess portion in the semiconductor (silicon) constituting a semiconductor layer SL and filling the recess portion with a light transmitting material, such as silicon oxide, having a refractive index different from the refractive index of the semiconductor. By providing the optical structure 141, the optical path length of light propagating through the semiconductor layer SL can be increased, thereby improving the sensitivity of the photoelectric conversion apparatus 100 in a near-infrared wavelength range. To increase the optical path length, the bottom portion (the portion closest to a first surface S1) of the optical structure 141 is preferably located in a third semiconductor region 113. In terms of reduction of crosstalk between pixels 101, the distance between the bottom portion (the portion closest to the first surface S1) of the optical structure 141 and the second surface S2 is preferably larger than the distance between a pixel isolation portion 131 and the second surface S2.

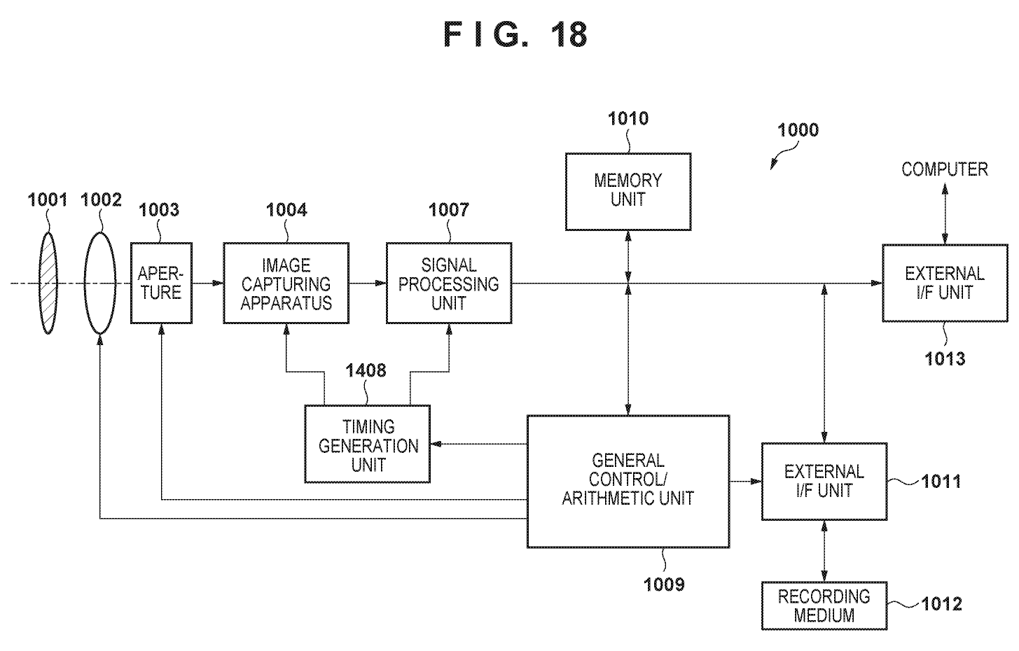

With reference to FIG. 18, a photoelectric conversion system according to the first application example will be described below. FIG. 18 is a block diagram showing the schematic configuration of a photoelectric conversion system according to the first application example.

The above-described photoelectric conversion apparatus 100 is applicable to various kinds of photoelectric conversion systems. Examples of photoelectric conversion systems to which the photoelectric conversion apparatus is applicable are a digital still camera, a digital camcorder, a monitoring camera, a copying machine, a facsimile apparatus, a mobile phone, an in-vehicle camera, and an observation satellite. A camera module including an optical system such as a lens and an image capturing apparatus is also included in the photoelectric conversion systems. FIG. 18 exemplarily shows the block diagram of a digital still camera as an example of these.

A photoelectric conversion system 1000 exemplarily shown in FIG. 18 includes an image capturing apparatus 1004 as an example of the photoelectric conversion apparatus. The photoelectric conversion system 1000 also includes a lens 1002 that forms an optical image of an object on the image capturing apparatus 1004, an aperture 1003 configured to change the amount of light passing through the lens 1002, and a barrier 1001 configured to protect the lens 1002. The lens 1002 and the aperture 1003 form an optical system (optical apparatus) that condenses light to the image capturing apparatus 1004. The image capturing apparatus 1004 is the photoelectric conversion apparatus 100 (image capturing apparatus) according to one of the above-described embodiments, and converts the optical image formed by the lens 1002 into an electrical signal.

The photoelectric conversion system 1000 also includes a signal processing unit 1007 that is an image generation unit configured to generate an image by processing an output signal output from the image capturing apparatus 1004. The signal processing unit 1007 functions as a processing apparatus that performs an operation of performing various kinds of correction and compression as needed, thereby outputting image data. The signal processing unit 1007 may be formed on a semiconductor substrate on which the image capturing apparatus 1004 is provided or may be formed on a semiconductor substrate different from the image capturing apparatus 1004. In addition, the image capturing apparatus 1004 and the signal processing unit 1007 may be formed on the same semiconductor substrate.

The photoelectric conversion system 1000 further includes a memory unit 1010 configured to temporarily store image data, and an external interface unit (external I/F unit) 1013 configured to communicate with an external computer or the like. Furthermore, the photoelectric conversion system 1000 includes a recording medium 1012 such as a semiconductor memory configured to record or read out image capturing data, and a recording medium control I/F unit 1011 configured to perform record or readout for the recording medium 1012. The recording medium control I/F unit 1011 and the recording medium 1012 can form a part of a recording apparatus. Note that the recording medium 1012 may be incorporated in the photoelectric conversion system 1000 or may be detachable.

Furthermore, the photoelectric conversion system 1000 includes a general control/arithmetic unit 1009 that controls various kinds of operations and the entire digital still camera, and a timing generation unit 1408 that outputs various kinds of timing signals to the image capturing apparatus 1004 and the signal processing unit 1007. The general control/arithmetic unit 1009 and the timing generation unit 1408 can form a part of a control apparatus configured to control an operation of the photoelectric conversion system 1000. In this example, the timing signal and the like may be input from the outside, and the photoelectric conversion system 1000 need only include at least the image capturing apparatus 1004, and the signal processing unit 1007 that processes an output signal output from the image capturing apparatus 1004.

The image capturing apparatus 1004 outputs an image capturing signal to the signal processing unit 1007. The signal processing unit 1007 executes predetermined signal processing for the image capturing signal output from the image capturing apparatus 1004, and outputs image data. The signal processing unit 1007 generates an image using the image capturing signal. Although not shown in FIG. 18, a display apparatus such as a display for displaying the generated image may be arranged in the photoelectric conversion system 1000. As described above, according to this application example, it is possible to implement the photoelectric conversion system 1000 to which the photoelectric conversion apparatus 100 (image capturing apparatus) according to one of the above-described embodiments is applied.

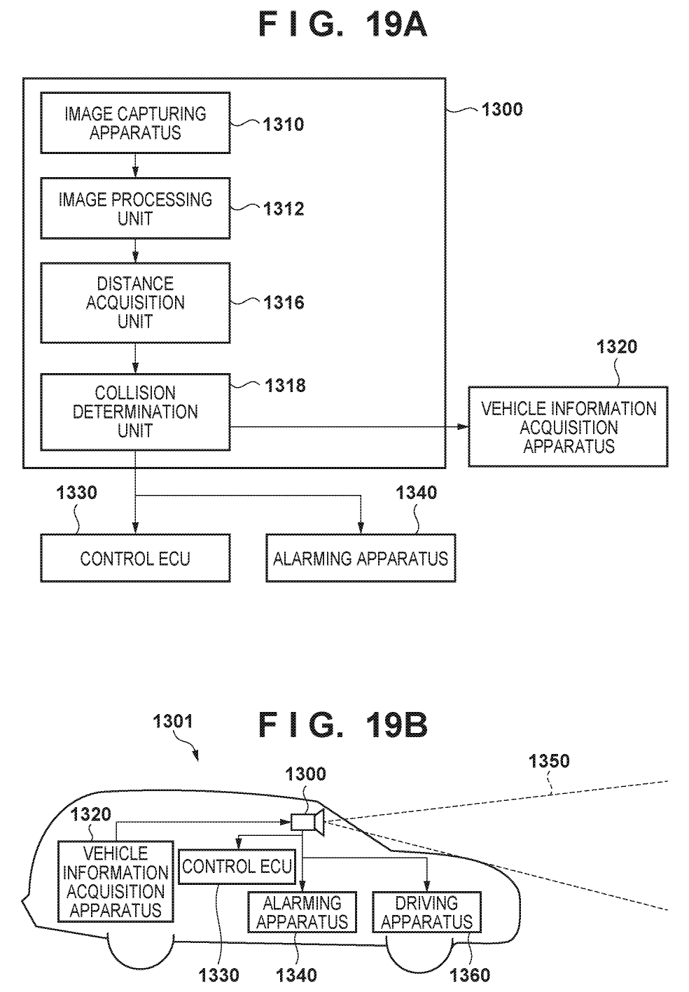

A photoelectric conversion system 1300 and a moving body 1301 according to the second application example will be described with reference to FIGS. 19A and 19B. FIGS. 19A and 19B are views showing the arrangement of the photoelectric conversion system 1300 and the moving body 1301 according to the second application example.

FIG. 19A shows an example of a photoelectric conversion system concerning an in-vehicle camera. The photoelectric conversion system 1300 includes an image capturing apparatus 1310. The image capturing apparatus 1310 is the photoelectric conversion apparatus 100 (image capturing apparatus) described in one of the above-described embodiments. The photoelectric conversion system 1300 includes an image processing unit 1312 that performs image processing for a plurality of image data acquired by the image capturing apparatus 1310. The photoelectric conversion system 1300 also includes a distance acquisition unit 1316 that calculates the distance up to a target object, and a collision determination unit 1318 that determines, based on the calculated distance, whether there is collision possibility. Here, the distance acquisition unit 1316 may acquire distance information up to a target object by using Time of Flight (ToF) method, or may acquire distance information by using parallax information or the like. That is, the distance information is information concerning a parallax, a defocus amount, a distance up to a target object, and the like. The collision determination unit 1318 may determine collision possibility using one of the pieces of distance information. The distance acquisition unit 1316 may be implemented by exclusively designed hardware, or may be implemented by a software module. The distance acquisition unit 1316 may be implemented by a Field Programmable Gate Array (FPGA), Application Specific Integrated Circuit (ASIC), or the like. Alternatively, the distance acquisition unit 1316 may be implemented by a combination of these.

The photoelectric conversion system 1300 is connected to a vehicle information acquisition apparatus 1320, and can acquire vehicle information such as a vehicle speed, a yaw rate, and a steering angle. The photoelectric conversion system 1300 is also connected to an ECU 1330 that is a control apparatus configured to output a control signal for generating a braking force to the vehicle based on the determination result of the collision determination unit 1318. Furthermore, the photoelectric conversion system 1300 is connected to an alarm apparatus 1340 that generates an alarm to the driver based on the determination result of the collision determination unit 1318. For example, if collision possibility is high as the determination result of the collision determination unit 1318, the ECU 1330 controls a driving apparatus (machine apparatus) 1360 to perform braking, releasing the accelerator pedal, or suppressing the engine output, thereby controlling the vehicle for avoiding collision and reducing damage. The alarm apparatus 1340 sounds an alarm, displays alarm information on the screen of a car navigation system or the like, or applies a vibration to the seat belt or a steering wheel, thereby making an alarm to the user.

In this application example, the periphery of the vehicle (moving body 1301), for example, the front or rear side is captured by the photoelectric conversion system 1300. FIG. 19B shows the photoelectric conversion system when capturing the front side (image capturing range 1350) of the vehicle. The vehicle information acquisition apparatus 1320 sends an instruction to the photoelectric conversion system 1300 or the image capturing apparatus 1310. With this configuration, it is possible to further improve the accuracy of distance measurement.

An example in which control is executed so as not to collide with another vehicle has been explained above. The photoelectric conversion system 1300 can also be applied to control of performing automated driving following another vehicle or control of performing automated driving without deviating from a lane. Furthermore, the photoelectric conversion system 1300 can be applied not only to a vehicle such as an automobile but also to, for example, a moving body (moving apparatus) such as a ship, an airplane, or an industrial robot. The moving body includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, a propeller of a moving body, or the like. In addition, the photoelectric conversion system can be applied not only to a moving body but also to equipment that broadly uses object recognition, such as an intelligent transport system (ITS).

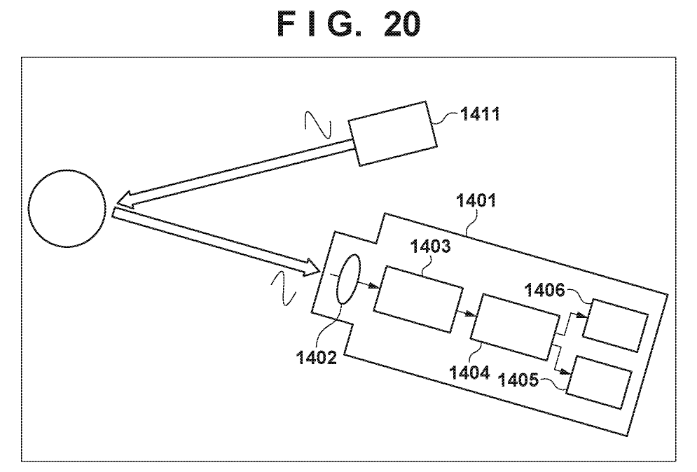

A photoelectric conversion system according to the third application example will be described with reference to FIG. 20. FIG. 20 is a block diagram showing an example of the arrangement of a distance image sensor 1401 as the photoelectric conversion system according to this embodiment.

As shown in FIG. 20, the distance image sensor 1401 includes an optical system 1402, a photoelectric conversion apparatus 1403, an image processing circuit 1404, a monitor 1405, and a memory 1406. Then, the distance image sensor 1401 can receive light (modulated light or pulsed light) projected from a light source apparatus 1411 toward an object and reflected by the surface of the object, thereby acquiring a distance image corresponding to the distance up to the object.

The optical system 1402 is formed by including one or a plurality of lenses, and guides image light (incident light) from the object to the photoelectric conversion apparatus 1403 and forms an image on the light-receiving surface (sensor portion) of the photoelectric conversion apparatus 1403.

As the photoelectric conversion apparatus 1403, the photoelectric conversion apparatus 100 of each of the above-described embodiments is applied, and a distance signal indicating a distance obtained from a light reception signal output from the photoelectric conversion apparatus 1403 is supplied to the image processing circuit 1404.

The image processing circuit 1404 performs image processing of creating a distance image based on the distance signal supplied from the photoelectric conversion apparatus 1403. Then, the distance image (image data) obtained by the image processing is supplied to and displayed on the monitor 1405, and supplied to and stored (recorded) in the memory 1406.

The distance image sensor 1401 having such arrangement can acquire, for example, a more correct distance image along with improvement in characteristic of pixels by applying the above-described photoelectric conversion apparatus 100.

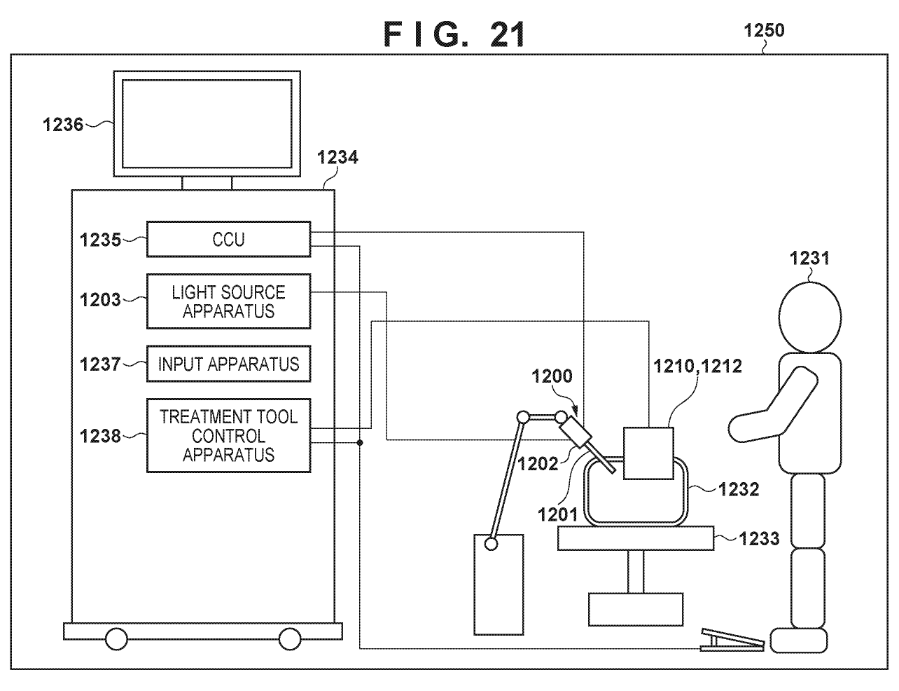

A photoelectric conversion system according to the fourth application example will be described with reference to FIG. 21. FIG. 21 is a view showing an example of the schematic arrangement of an endoscopic surgery system 1250 as the photoelectric conversion system according to fourth application example.

FIG. 21 shows a state in which an operator (doctor) 1231 operates on a patient 1232 on a patient bed 1233 using the endoscopic surgery system 1250. As shown in FIG. 21, the endoscopic surgery system 1250 is formed from an endoscope 1200, a surgical tool 1210, and a cart 1234 on which various apparatuses for endoscopic surgery are mounted.

The endoscope 1200 includes a lens barrel 1201 including a region of a predetermined length from the distal end, which is inserted into the body cavity of the patient 1232, and a camera head 1202 connected to the proximal end of the lens barrel 1201. In the example shown in FIG. 21, the endoscope 1200 formed as a so-called hard mirror including the hard lens barrel 1201 is shown but the endoscope 1200 may be formed as a so-called soft mirror including a soft lens barrel.

An opening in which an objective lens is fitted is provided at the distal end of the lens barrel 1201. A light source apparatus 1203 is connected to the endoscope 1200, and light generated by the light source apparatus 1203 is guided to the distal end of the lens barrel by a light guide extended inside the lens barrel 1201, and is emitted to an observation target in the body cavity of the patient 1232 via the objective lens. Note that the endoscope 1200 may be a forward-viewing endoscope or may be a forward-oblique viewing endoscope or side-viewing endoscope.

An optical system and a photoelectric conversion apparatus are provided in the camera head 1202, and reflected light (observation light) from the observation target is focused by the optical system onto the photoelectric conversion apparatus. The observation light is photoelectrically converted by the photoelectric conversion apparatus to generate an electrical signal corresponding to the observation light, that is, an image signal corresponding to an observation image. As the photoelectric conversion apparatus, the photoelectric conversion apparatus 100 (image capturing apparatus) described in each of the above-described embodiments can be used. The image signal is transmitted as RAW data to a Camera Control Unit (CCU) 1235.

The CCU 1235 is formed by a Central Processing Unit (CPU), a Graphics Processing Unit (GPU), and the like, and comprehensively controls the operations of the endoscope 1200 and a display apparatus 1236. Furthermore, the CCU 1235 receives an image signal from the camera head 1202, and performs, for the image signal, various kinds of image processes such as development processing (demosaic processing) for displaying an image based on the image signal.

Under the control of the CCU 1235, the display apparatus 1236 displays the image based on the image signal having undergone the image processing by the CCU 1235.

The light source apparatus 1203 is formed from a light source such as a Light Emitting Diode (LED), and supplies, to the endoscope 1200, irradiation light at the time of imaging an operation portion or the like.

An input apparatus 1237 is an input interface to the endoscopic surgery system 1250. The user can input various kinds of information or instructions to the endoscopic surgery system 1250 via the input apparatus 1237.

A treatment tool control apparatus 1238 controls driving of an energy treatment tool 1212 for ablation or incision of the tissue, sealing of a blood vessel, or the like.

The light source apparatus 1203 that supplies, to the endoscope 1200, irradiation light at the time of imaging an operation portion can be formed from, for example, a white light source formed by an LED, a laser light source, or a combination thereof. If the white light source is formed by a combination of RGB laser light sources, it is possible to accurately control the output intensity and output timing of each color (each wavelength), and thus the light source apparatus 1203 can adjust the white balance of a captured image. In this case, the observation target is time-divisionally irradiated with laser beams from the RGB laser light sources, respectively, and driving of the image sensor of the camera head 1202 is controlled in synchronism with the irradiation timings, thereby making it possible to time-divisionally capture images respectively corresponding to R, G, and B. In this method, it is possible to obtain a color image without providing color filters in the image sensor.

Driving of the light source apparatus 1203 may be controlled to change the intensity of light to be output at every predetermined time interval. It is possible to time-divisionally acquire images by controlling driving of the image sensor of the camera head 1202 in synchronism with the timing of changing the intensity of the light, and combine the images, thereby generating an image of a high dynamic range without so-called shadow detail loss or highlight detail loss.

The light source apparatus 1203 may be configured to supply light in a predetermined wavelength band corresponding to special light observation. In special light observation, for example, the wavelength dependency of light absorption in the body tissue is used. More specifically, by performing irradiation with light in a narrow band, as compared with irradiation light (that is, white light) at the time of normal observation, predetermined tissue such as a blood vessel in the mucous membrane surface layer is captured with high contrast. Alternatively, in special light observation, fluorescence observation for obtaining an image by using fluorescence generated by performing radiation with excitation light may be performed. In fluorescence observation, it is possible to, for example, irradiate body tissue with excitation light and observe fluorescence from the body tissue, or locally inject a reagent such as indocyanine green (ICG) to body tissue while irradiating the body tissue with excitation light corresponding to the fluorescence wavelength of the reagent, thereby obtaining a fluorescence image. The light source apparatus 1203 can be configured to supply narrow band light and/or excitation light corresponding to such special light observation.

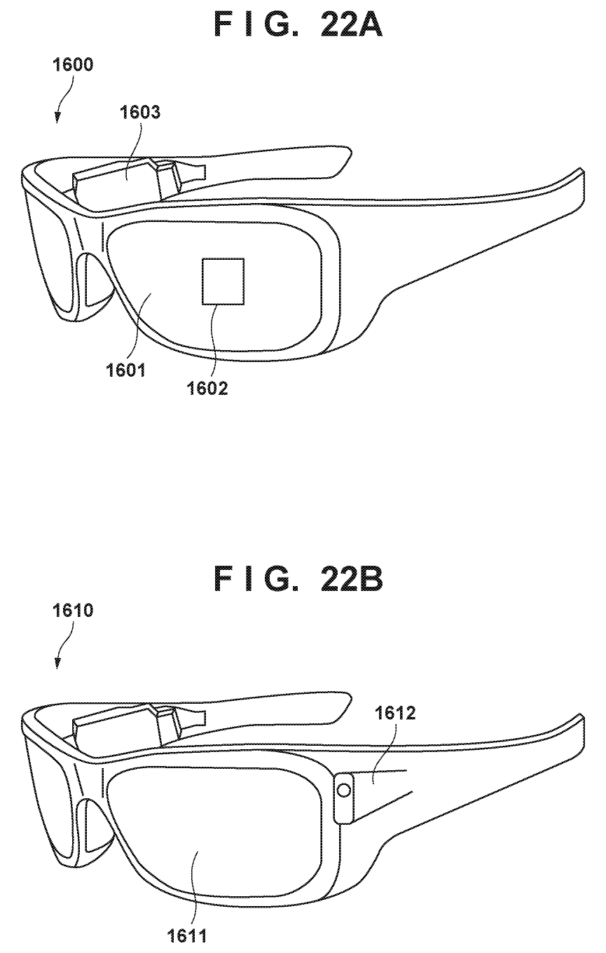

A photoelectric conversion system according to the fifth application example will be described with reference to FIGS. 22A and 22B. FIG. 22A describes glasses 1600 (smartglasses) as the photoelectric conversion system according to the fifth application example. The glasses 1600 include a photoelectric conversion apparatus 1602. The photoelectric conversion apparatus 1602 is the photoelectric conversion apparatus 100 (image capturing apparatus) described in each of the above embodiments. A display apparatus including the light emitting apparatus such as an OLED or LED may be provided on the back surface side of a lens 1601. One or a plurality of photoelectric conversion apparatuses 1602 may be provided. Alternatively, a plurality of kinds of photoelectric conversion apparatuses may be used in combination. The arrangement position of the photoelectric conversion apparatus 1602 is not limited to that shown in FIG. 22A.

The glasses 1600 further include a control apparatus 1603. The control apparatus 1603 functions as a power supply that supplies electric power to the photoelectric conversion apparatus 1602 and the above-described display apparatus. In addition, the control apparatus 1603 controls the operations of the photoelectric conversion apparatus 1602 and the display apparatus. An optical system configured to condense light to the photoelectric conversion apparatus 1602 is formed on the lens 1601.

FIG. 22B describes glasses 1610 (smartglasses) according to an application example. The glasses 1610 include a control apparatus 1612, and a photoelectric conversion apparatus corresponding to the photoelectric conversion apparatus 1602 and a display apparatus are mounted on the control apparatus 1612. The photoelectric conversion apparatus in the control apparatus 1612 and an optical system configured to project light emitted from the display apparatus are formed in a lens 1611, and an image is projected to the lens 1611. The control apparatus 1612 functions as a power supply that supplies electric power to the photoelectric conversion apparatus and the display apparatus, and controls the operations of the photoelectric conversion apparatus and the display apparatus. The control apparatus may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a plan view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display apparatus according to this application example can include a photoelectric conversion apparatus including a light receiving element, and control a displayed image of the display apparatus based on the line-of-sight information of the user from the photoelectric conversion apparatus.

More specifically, the display apparatus decides a first visual field region at which the user is gazing and a second visual field region other than the first visual field region based on the line-of-sight information. The first visual field region and the second visual field region may be decided by the control apparatus of the display apparatus, or those decided by an external control apparatus may be received. In the display region of the display apparatus, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority may be decided from the first display region and the second display region based on line-of-sight information. The first visual field region and the second visual field region may be decided by the control apparatus of the display apparatus, or those decided by an external control apparatus may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target object in the line of sight from the image of the eyeball using the image of the eyeball and the direction of actual viewing of the eyeball in the image as supervised data. The AI program may be held by the display apparatus, the photoelectric conversion apparatus, or an external apparatus. If the external apparatus holds the AI program, it is transmitted to the display apparatus via communication.

When performing display control based on line-of-sight detection, smartglasses further including a photoelectric conversion apparatus configured to capture the image of the outside can preferably be applied. The smartglasses can display the captured outside image information in real time.

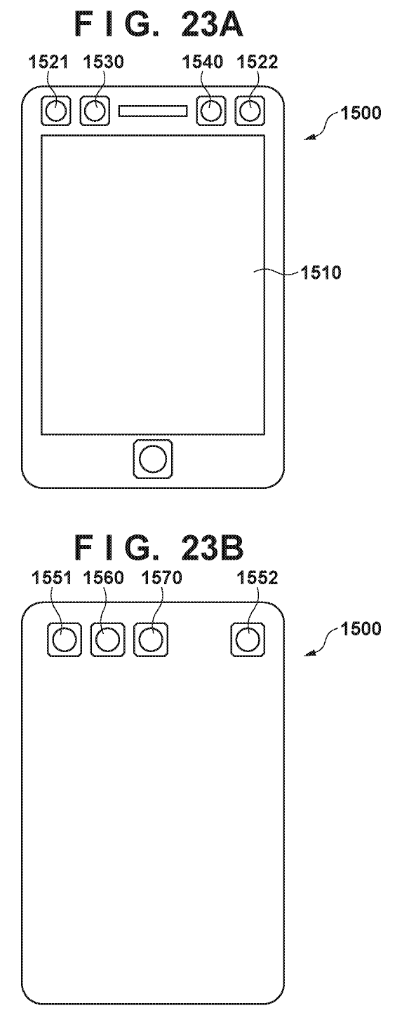

The sixth application example will be described with reference to FIGS. 23A and 23B. The above-described photoelectric conversion apparatus and photoelectric conversion system may be applied to, for example, electronic equipment such as a so-called smartphone or tablet.

FIGS. 23A and 23B are views showing an example of electronic equipment 1500 on which the photoelectric conversion apparatus is mounted. FIG. 23A shows the front surface side of the electronic equipment 1500, and FIG. 23B shows the back surface side of the electronic equipment 1500.

As shown in FIG. 23A, a display 1510 that displays an image is arranged at the center of the front surface of the electronic equipment 1500. Then, front cameras 1521 and 1522 for each of which the above-described photoelectric conversion apparatus 100 is used, an IR light source 1530 that emits infrared rays, and a visible light source 1540 that emits visible light are arranged along the upper side of the front surface of the electronic equipment 1500.

As shown in FIG. 23B, rear cameras 1551 and 1552 for each of which the above-described photoelectric conversion apparatus 100 is used, an IR light source 1560 that emits infrared rays, and a visible light source 1570 that emits visible light are arranged along the upper side of the back surface of the electronic equipment 1500.

By applying the above-described photoelectric conversion apparatus 100, the electronic equipment 1500 having the above arrangement can capture, for example, an image of higher quality. Note that the photoelectric conversion apparatus can be applied to electronic equipment such as an infrared sensor, a distance measurement sensor using an active infrared source, a security camera, or a personal or biometric authentication camera. This can improve the accuracy and performance of the electronic equipment.

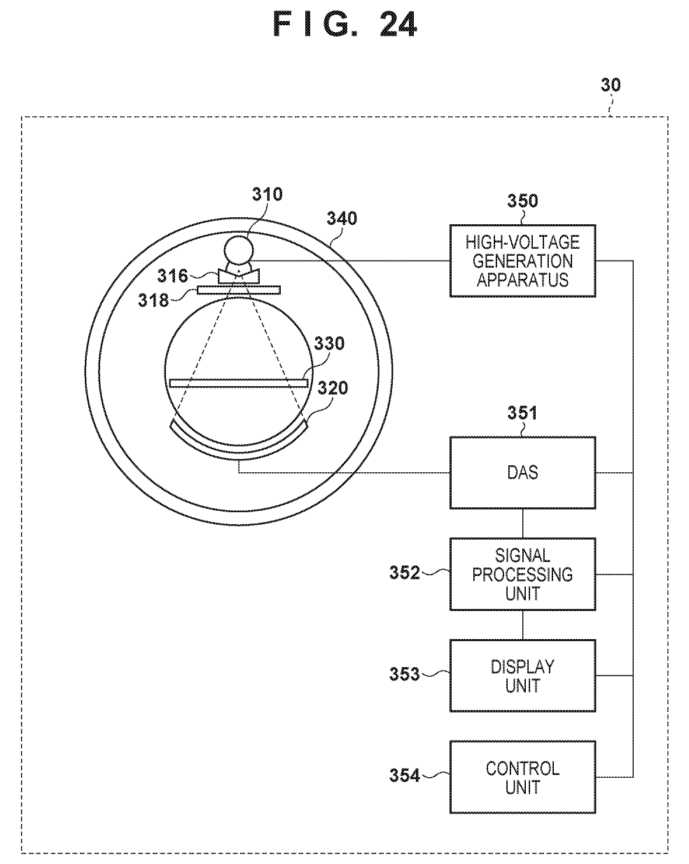

FIG. 24 is a block diagram of an X-ray CT apparatus according to the seventh application example. The above-described photoelectric conversion apparatus 100 is applicable to a detector of the X-ray CT apparatus. An X-ray CT apparatus 30 according to this application example includes an X-ray generation unit 310, a wedge 316, a collimator 318, an X-ray detection unit 320, a top plate 330, a rotating frame 340, and a high-voltage generation apparatus 350. The X-ray CT apparatus 30 also includes a Data Acquisition System (DAS) 351, a signal processing unit 352, a display unit 353, and a control unit 354.

The X-ray generation unit 310 is formed from, for example, a vacuum tube that generates X-rays. The vacuum tube of the X-ray generation unit 310 is supplied with a filament current and a high voltage from the high-voltage generation apparatus 350. When thermoelectrons are emitted from a cathode (filament) to an anode (target), X-rays are generated.

The wedge 316 is a filter that adjusts the amount of X-rays emitted from the X-ray generation unit 310. The wedge 316 attenuates the amount of X-rays so that the X-rays emitted from the X-ray generation unit 310 to an object have a predetermined distribution. The collimator 318 is formed from a lead plate that narrows the irradiation range of the X-rays having passed through the wedge 316. The X-rays generated by the X-ray generation unit 310 are formed in a cone beam shape via the collimator 318, and the object on the top plate 330 is irradiated with the X-rays.

The X-ray detection unit 320 is formed using the above-described photoelectric conversion apparatus 100. The X-ray detection unit 320 detects the X-rays having passed through the object from the X-ray generation unit 310, and outputs a signal corresponding to the amount of the X-rays to the DAS 351.

The rotating frame 340 is annular, and is configured to be rotatable. The X-ray generation unit 310 (the wedge 316 and the collimator 318) and the X-ray detection unit 320 are arranged to face each other in the rotating frame 340. The X-ray generation unit 310 and the X-ray detection unit 320 can rotate together with the rotating frame 340.

The high-voltage generation apparatus 350 includes a boosting circuit, and outputs a high voltage to the X-ray generation unit 310. The DAS 351 includes an amplification circuit and an A/D conversion circuit, and outputs, as digital data, a signal from the X-ray detection unit 320 to the signal processing unit 352.

The signal processing unit 352 includes a Central Processing Unit (CPU), a Read Only Memory (ROM), and a Random Access Memory (RAM), and can execute image processing and the like for the digital data. The display unit 353 includes a flat display apparatus or the like, and can display an X-ray image. The control unit 354 includes a CPU, a ROM, a RAM, and the like, and controls the operation of the overall X-ray CT apparatus 30.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-020247, filed February 10, 2025, which is hereby incorporated by reference herein in its entirety.

What is claimed is:

1. A photoelectric conversion apparatus including a plurality of pixels, comprising
a semiconductor layer including a first surface and a second surface, a plurality of first electrodes arranged in contact with the first surface, and at least one second electrode arranged in contact with the second surface,
wherein
the semiconductor layer includes a pixel isolation portion constituted by an insulator arranged between adjacent pixels of the plurality of pixels,
each pixel includes a first semiconductor region of a first conductivity type arranged in the semiconductor layer and electrically connected to one of the plurality of first electrodes, and a second semiconductor region of a second conductivity type arranged in the semiconductor layer and electrically connected to the second electrode,
the semiconductor layer includes a third semiconductor region of the second conductivity type being in contact with the second electrode and electrically connected to the second semiconductor region, and
a contact region between the second electrode and the second surface overlaps the insulator in an orthogonal projection to the first surface.

2. The apparatus according to claim 1, wherein
the third semiconductor region is arranged to extend across the plurality of pixels.

3. The apparatus according to claim 2, wherein
the third semiconductor region includes a portion arranged between the second surface and the pixel isolation portion.

4. The apparatus according to claim 2, wherein
the pixel isolation portion includes a portion extending from the first surface to a position in the third semiconductor region.

5. The apparatus according to claim 1, wherein
the semiconductor layer includes a fourth semiconductor region of the second conductivity type arranged in contact with a side surface of the pixel isolation portion.

6. The apparatus according to claim 5, wherein
the fourth semiconductor region is arranged to electrically connect the second semiconductor region and the third semiconductor region.

7. The apparatus according to claim 6, wherein
the fourth semiconductor region is arranged spaced apart from the first surface.

8. The apparatus according to claim 6, wherein
the fourth semiconductor region is arranged not to surround the first semiconductor region.

9. The apparatus according to claim 1, wherein
the plurality of pixels are arranged to form a rectangular lattice, and
the contact region is arranged to overlap a lattice point of the rectangular lattice.

10. The apparatus according to claim 1, wherein
the number of the at least one second electrode is smaller than the number of the plurality of pixels.

11. The apparatus according to claim 1, wherein
in a region where the at least one second electrode is not arranged, the pixel isolation portion extends from the first surface to the second surface.

12. The apparatus according to claim 1, wherein
a width of a portion of the pixel isolation portion closest to the second surface is smaller than a width of the pixel isolation portion at the first surface.

13. The apparatus according to claim 1, wherein
a width of the contact region is smaller than a width of a portion of the pixel isolation portion closest to the second surface.

14. The apparatus according to claim 1, wherein
a width of the contact region is smaller than a width of the pixel isolation portion at the first surface.

15. The apparatus according to claim 1, wherein
a wiring pattern connected to the second electrode is provided, and a width of the wiring pattern is smaller than a width of the pixel isolation portion.

16. The apparatus according to claim 1, wherein
the pixel isolation portion includes a first portion spaced apart from the second surface, and a second portion in contact with the second surface.

17. The apparatus according to claim 1, wherein
the pixel isolation portion includes a first portion and a second portion, and a distance between the second surface and the first portion is smaller than a distance between the second surface and the second portion.

18. The apparatus according to claim 16, wherein
the plurality of pixels are arranged to form a rectangular lattice, and
the contact region and the first portion are arranged to overlap a lattice point of the rectangular lattice.

19. The apparatus according to claim 18, wherein
the second portion is arranged between adjacent lattice points of the rectangular lattice.

20. A photoelectric conversion system comprising:
a photoelectric conversion apparatus defined in claim 1; and
a signal processing unit configured to process a signal output from the photoelectric conversion apparatus.
